(19) United States
(12) Patent Application Publication
(10) Pub. No.: US 2009/0109152 A1
(43) Pub. Date: Apr. 30, 2009

(54) Monitor with multi-module communication function

(76) Inventors: James Chu, Taipei (TW); H.C. Ho, Taipei (TW)

Correspondence Address: BIRCH STEWART KOLASCH & BIRCH, PO BOX 747, FALLS CHURCH, VA, 22040-0747, US

(21) Appl. No.: 11/976,876

(22) Filed: Oct. 29, 2007

(51) Int. Cl. G09G 3/36; H05K 5/00; H04L 12/66

(52) U.S. Cl. 345/87; 370/352

(57) ABSTRACT

A monitor with multi-module communication function includes a display screen framed in a housing, and a base, to a top of which the housing is mounted. At least one set of USB sockets and at least one set of PSTN jacks are externally provided on the housing or the base at predetermined positions; and an automatic switch circuit and a microprocessor with a memory are internally provided in the housing. The automatic switch circuit is connected to a personal computer and a VoIP phone via the USB sockets, and to a PSTN phone and a PSTN system provider via the PSTN jacks. Therefore, a user can make and receive VoIP calls via the PSTN phone at reduced call cost.

### FIELD OF THE INVENTION

The present invention relates to a monitor with multi-module communication function, and more particularly to a monitor that enables automatic switch between different communication modules to provide a more comfortable computer communication environment and to reduce call cost.

### BACKGROUND OF THE INVENTION

In a conventional monitor with a liquid crystal display (LCD), the LCD is framed in a housing, and the housing is then mounted on a base. The housing is provided with a series of function adjusting keys and a power switch, and the monitor functions only as a standard display.

The conventional LCD is connected to a case (that is, a computer case) via a transmission cable, and a PSTN (Public Switch Telephone Network) phone or a Skype phone is connected to a phone jack or a USB (universal serial bus) socket, respectively, on the case via a phone cord or a USB link cable, respectively, so that a user may make and receive calls via a PSTN or a VoIP (voice over Internet phone) system.

However, it is known that the computer case of a personal computer is usually positioned on a floor, and relatively long link cables are therefore required for connecting the various communication modules to the computer case to cause inconveniences to users.

It is therefore tried by the inventor to develop a monitor with multi-module communication function to overcome the problems in connecting communication modules to the computer case via long link cables.

### SUMMARY OF THE INVENTION

A primary object of the present invention is to provide a monitor with multi-module communication function, so as to provide a more comfortable computer communication environment and to reduce call cost.

To achieve the above and other objects, the monitor with multi-module communication function according to the present invention includes a display screen framed in a housing, and a base, to a top of which the housing is mounted. At least one set of USB sockets and at least one set of PSTN jacks are externally provided on the housing or the base at predetermined positions; and an automatic switch circuit and a microprocessor with memory are internally provided in the housing. The USB sockets and the PSTN jacks are electrically connected to the automatic switch circuit and the microprocessor, so that multiple types of communication modules, such as PSTN phone and VoIP phone, may be connected to the automatic switch circuit and the microprocessor via the USB sockets and PSTN jacks. Therefore, a user can conveniently make and receive VoIP calls via the PSTN phone at reduced call cost.

Moreover, the housing is provided with a handset/hand-free switch, so that a user may more conveniently communicate with others via computer digital communication and/or PSTN mode without the need of always holding a handset of a phone.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a front perspective view of a monitor with multi-module communication function according to the present invention, wherein an automatic switch circuit is provided on a front of a housing of the monitor;

FIG. 2 is a bottom view showing the monitor of the present invention is provided at a rear lower side of the housing with USB sockets and PSTN jacks;

FIG. 3 is a rear view showing the monitor of the present invention is provided at a rear side of a base thereof with USB sockets and PSTN jacks;

FIG. 4 is a rear view showing the monitor of the present invention is provided at a rear lower side of the housing thereof with USB sockets and PSTN jacks; and

FIG. 5 shows a PSTN phone and a VoIP phone that may be connected to the monitor of the present invention.

### DETAILED DESCRIPTION OF THE PREFERRED EMBODIMENTS

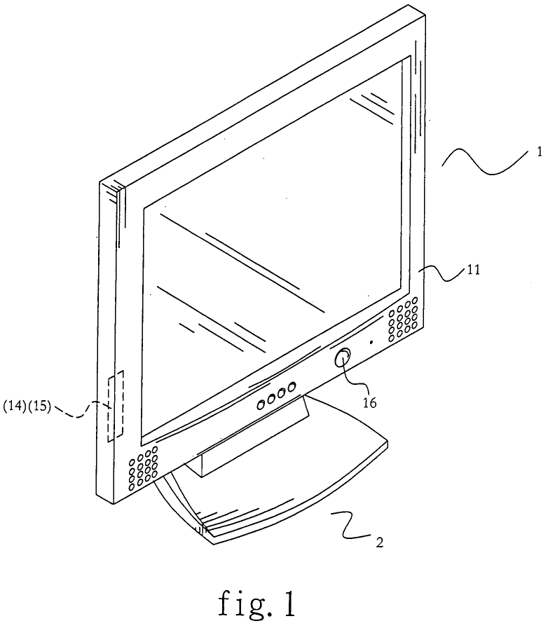

Please refer to FIG. 1 that is a front perspective view of a monitor with multi-module communication function according to the present invention. As shown, the monitor includes a display screen 1 framed in a housing 11, and a base 2, to a top of which the housing 11 is mounted.

The display screen 1 in the housing 11 is a liquid crystal display (LCD). In addition to the standard display function for using in a general video environment, the monitor of the present invention is also provided with a plurality of different communication modules for using in different communication environments, such as PSTN and VoIP systems.

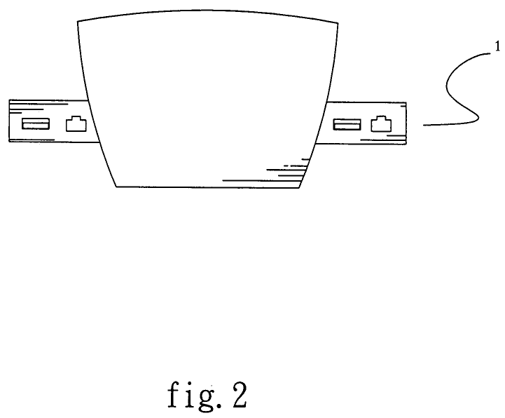

The housing 11 is internally provided at predetermined positions with a microprocessor 14 having a memory, and an automatic switch circuit 15; and externally provided at predetermined positions with at least one set of PSTN jacks 12 and at least one set of USB sockets 13. In a first embodiment of the present invention as shown in FIG. 2, the PSTN jacks 12 and the USB sockets 13 are provided at a lower side of the display screen 1 facing toward a desk top, so as to keep the integrity of the display screen 1 without adversely affecting an overall visual beautifulness of the monitor.

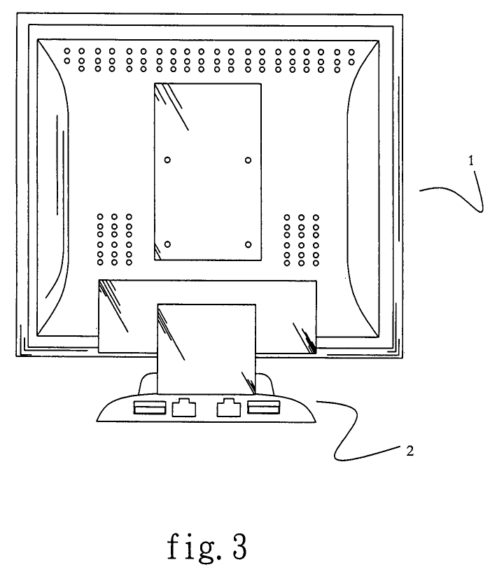

In a second embodiment of the present invention as shown in FIG. 3, the PSTN jacks 12 and the USB sockets 13 are provided at a rear side of the base 2 of the monitor of the present invention to achieve the effect of space reduction and maintain the integrity of the display screen 1.

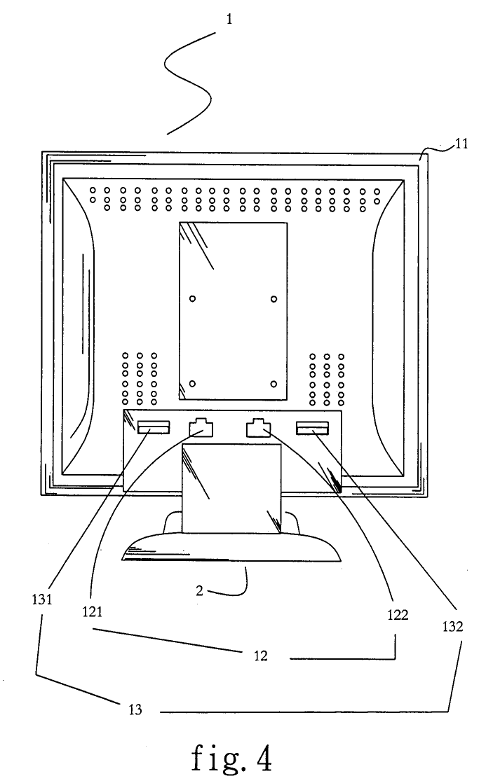

In a third embodiment of the present invention as shown in FIG. 4, the housing 11 of the display screen 1 is directly provided at predetermined positions, such as at a rear lower side of the housing 11, with recesses using molds during manufacturing of the housing 11, so that necessary elements may be mounted in the preformed recesses to form the PSTN jacks 12 and the USB sockets 13.

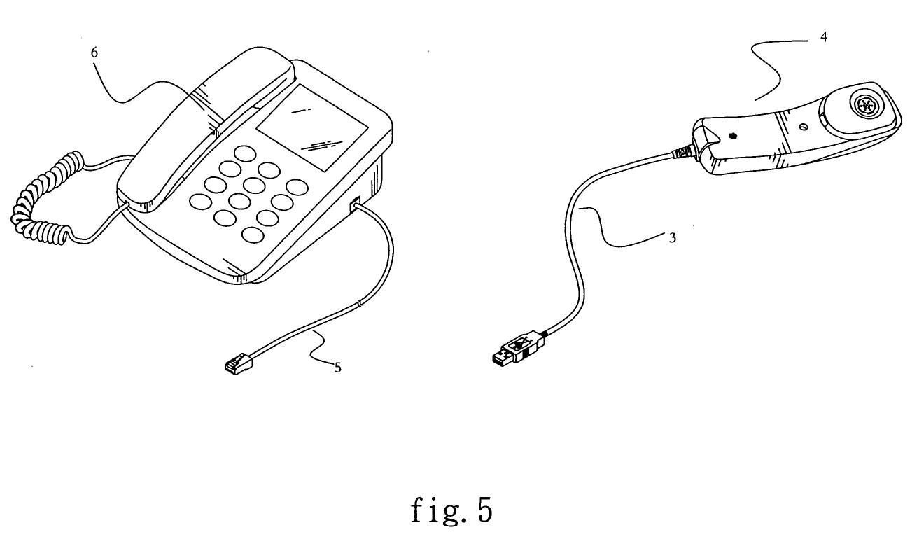

Please refer to FIG. 5. The monitor of the present invention in any of the above-mentioned four embodiments may have a VoIP phone 4 and/or a PSTN phone 6 connected thereto. The monitor of the present invention may be connected via a PSTN phone cord (not shown) to a phone box (not shown) of a PSTN system provider, and via another PSTN phone cord 5 to the PSTN phone 6, so as to receive calls in a PSTN communication mode. Meanwhile, the monitor of the present invention may be connected via a USB link cable (not shown) to a personal computer (not shown) for receiving VoIP digital communication signals. The received VoIP signals are processed by the microprocessor 14 (refer to FIG. 1) and then flows to the PSTN phone cord 5, and a user may use the PSTN phone 6 to receive and transmit voice signals in a VoIP communication mode.

As can be seen from FIG. 4, the USB sockets 13 are divided into a USB IN socket 131 and a USB OUT socket 132. The monitor of the present invention is connected at the USB IN socket 131 to the personal computer via the USB link cable for receiving and transmitting VoIP signals. In this manner, a user may communicate with others in VoIP mode by using the VoIP phone 4. Since the VoIP signals may be converted by the microprocessor 14, even if the phone picked up by the user is the PSTN phone 6, the PSTN phone 6 may still function either in the PSTN or the VoIP communication mode.

The PSTN jacks 12 are divided into a PSTN IN jack 121 and a PSTN OUT jack 122. The PSTN phone cord 5 is connected at an end to the PSTN OUT jack 122 and at the other end to the PSTN phone 6 to thereby connect the PSTN phone 6 to the automatic switch circuit 15 in the housing 11 of the monitor of the present invention. Another PSTN phone cord is connected at an end to the PSTN IN jack 121 and at the other end to the PSTN provider to thereby connect the automatic switch circuit 15 to the PSTN system provider.

With the automatic switch circuit 15, a loop is formed between the USB sockets 13 and the PSTN jacks 12 for converting signals.

The microprocessor 14 controls the automatic switch circuit 15, reads out data from the memory of the microprocessor 14, and writes data into the memory.

The housing 11 of the display screen 1 is provided with a handset/hand-free switch 16, which is an auto/manual switch module. No matter the computer, to which the monitor of the present invention is connected, is on or off, the user need not hold a handset of the PSTN phone 6 or the VoIP phone 4 with one hand during voice communication.

When the computer is off or in a shut-down state, the user may simply pick up the handset of the PSTN phone 6 and dial. The voice signals will be transmitted to the PSTN system provider via the link cable plugged in the PSTN OUT jack 122, and the user is linked via dial-up access to a receiver who uses a PSTN phone, a cell phone, or a VoIP phone. On the other hand, when a remote caller wants to communicate with a user using the monitor of the present invention via a PSTN phone or a cell phone, the user's PSTN phone 6 connected to the housing 11 of the display screen 1 will ring to remind the user to answer the phone in PSTN mode.

When the computer is on or in a started state, one of the following two conditions might occur:

In a first condition, it is unknown whether a receiver would answer the phone in PSTN or VoIP mode. In this case, the user, i.e. the caller, may use any one of the two communication modes to make the phone call. No matter the call is made via the PSTN phone 6 or the VoIP phone 6, the voice signals would be transmitted to the automatic switch circuit 15, which would automatically determine and select either VoIP or PSTN point-to-point IP phone mode. Once the caller is connected to the remote receiver, the whole voice communication is proceeded with in the mold automatically determined and selected via the automatic switch circuit 15. In this manner, call cost may be reduced as much as possible.

In a second condition, it is unknown whether a remote caller would make a call in VoIP or PSTN mode. In this case, when the voice signals from the remote caller are received by the monitor of the present invention, they are automatically converted by the automatic switch circuit 15 into a corresponding voice transmission mode, and the user of the present invention needs only to pick up the handset of the PSTN phone 6 to answer the call and talk. In other words, as shown in FIG. 5, the receiver needs only to pick up the PSTN phone 6 to talk with the caller in VoIP or PSTN mode without the necessity of using the VoIP phone 4 and the USB link cable 3 to enable the VoIP communication mode.

What is claimed is:

1. A monitor with multi-module communication function, comprising a display screen framed in a housing, and a base, to a top of which the housing is mounted; the base being provided at predetermined positions with at least one set of USB sockets and at least one set of PSTN jacks, and the housing being internally provided with a microprocessor having a memory, and an automatic switch circuit;
the automatic switch circuit being connected to a VoIP phone and a personal computer via USB link cables that are connected at an end to the USB sockets, and to a PSTN phone and a PSTN system provider via PSTN phone cords that are connected at an end to the PSTN jacks, so as to proceed with conversion between VoIP and PSTN signals.

2. The monitor with multi-module communication function as claimed in claim 1, wherein the at least one set of USB sockets includes a USB IN socket and a USB OUT socket.

3. The monitor with multi-module communication function as claimed in claim 2, wherein one of the USB link cables for connecting the automatic switch circuit to the personal computer is connected to the USB IN socket.

4. The monitor with multi-module communication function as claimed in claim 2, wherein one of the USB link cables for connecting the automatic switch circuit to the VoIP phone is connected to the USB OUT socket.

5. The monitor with multi-module communication function as claimed in claim 1, wherein the at least one set of PSTN jacks is provided with a PSTN IN jack and a PSTN OUT jack.

6. The monitor with multi-module communication function as claimed in claim 5, wherein one of the PSTN phone cords for connecting the automatic switch circuit to the PSTN system provider is connected at an end to the PSTN IN jack.

7. The monitor with multi-module communication function as claimed in claim 5, wherein one of the PSTN phone cords for connecting the automatic switch circuit to the PSTN phone is connected at an end to the PSTN OUT jack.

8. The monitor with multi-module communication function as claimed in claim 1, wherein the housing is externally provided at predetermined positions with at least one set of USB sockets and at least one set of PSTN jacks.

9. The monitor with multi-module communication function as claimed in claim 1, wherein the housing is externally provided at a predetermined position with a handset/hand-free switch.
